(19) United States
(12) Patent Application Publication
(10) Pub. No.: US 2026/0071321 A1
(43) Pub. Date: Mar. 12, 2026

(54) SUBSTRATE TREATMENT APPARATUS

(71) Applicant: TOKYO ELECTRON LIMITED, Tokyo (JP)

(72) Inventors: Motoi YAMAGATA, Tokyo (JP); Hiroshi SONE, Tokyo (JP); Masaki SUGIURA, Tokyo (JP)

(21) Appl. No.: 18/835,180

(22) PCT Filed: Jan. 25, 2023
(86) PCT No.: PCT/JP2023/002251

§ 371 Date: Apr. 22, 2025

(30) Foreign Application Priority Data
Feb. 1, 2022 (JP) 2022-014449

(51) Int. Cl. C23C 16/44; C23C 14/50; C23C 14/56; C23C 16/458

(52) U.S. Cl. CPC C23C 16/4409; C23C 14/505; C23C 14/564; C23C 16/4584

(57) ABSTRACT

Provided is a substrate treatment apparatus capable of reducing torque for rotating a placing table. This substrate treatment apparatus is provided in a treatment container and comprises: a placing table on which a substrate is placed; a rotary shaft that supports the placing table; a housing that rotatably supports the rotary shaft; a magnetic fluid seal provided between the rotary shaft and the housing; and a heater that adjusts the temperature of the magnetic fluid seal.

### TECHNICAL FIELD

The present disclosure relates to a substrate processing apparatus.

### BACKGROUND

Patent Document 1 discloses a magnetic fluid sealing rotary introducer having a mechanism for sealing a rotation shaft connected to a vacuum chamber with a plurality of magnetic fluid seal stages, in which adhesion of unreacted gases and reaction products is prevented by a temperature control mechanism built into or externally attached to the sealing mechanism.

### Prior Art Documents

### Patent Documents

Patent document 1: Japanese Laid-open Patent Publication No. 2001-74140

### SUMMARY

### Problems to Be Resolved by the Invention

One aspect of the present disclosure provides a substrate processing apparatus for reducing torque for rotating a placing table.

### Means for Solving the Problems

A substrate processing apparatus according to one aspect of the present disclosure comprises a placing table disposed in the processing chamber and on which a substrate is placed, a rotation shaft configured to support the placing table, a housing configured to rotatably support the rotation shaft, a magnetic fluid seal disposed between the rotation shaft and the housing, and a heater configured to adjust a temperature of the magnetic fluid seal.

### Effect of the Invention

In accordance with one aspect of the present disclosure, it is possible to provide a substrate processing apparatus for reducing torque for rotating a placing table.

### BRIEF DESCRIPTION OF THE DRAWINGS

FIG. 1 is a cross-sectional view showing an example of a configuration of a substrate processing apparatus according to an embodiment during rotation of a placing table.

FIG. 2 is a cross-sectional view showing an example of a configuration of the substrate processing apparatus according to the embodiment during cooling of the placing table.

FIG. 3 shows an example of a partially enlarged cross-sectional view of a rotation device near a rotation shaft.

FIG. 4 shows an example of a graph showing a rotational speed of a rotation shaft and torque for rotating the rotation shaft.

FIG. 5 shows an example of a graph showing relationship between the rotational speed and the rotational torque of the rotation shaft.

FIG. 6 shows an example of a cross-sectional view of a slip ring.

FIG. 7 shows an example of a plan view of the slip ring viewed from above.

### DETAILED DESCRIPTION

Hereinafter, embodiments of the present disclosure will be described with reference to the accompanying drawings. Like reference numerals will be used for like parts throughout the drawings, and redundant description thereof may be omitted.

### <Substrate Processing Apparatus 1>

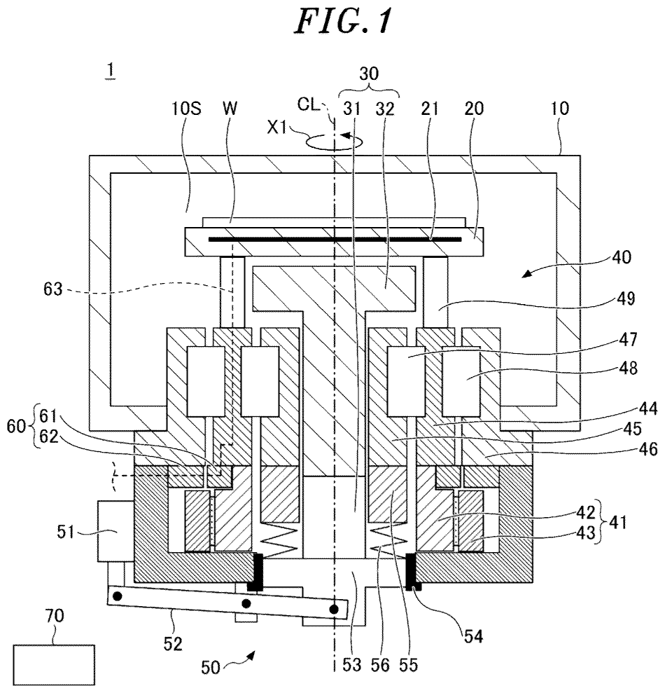

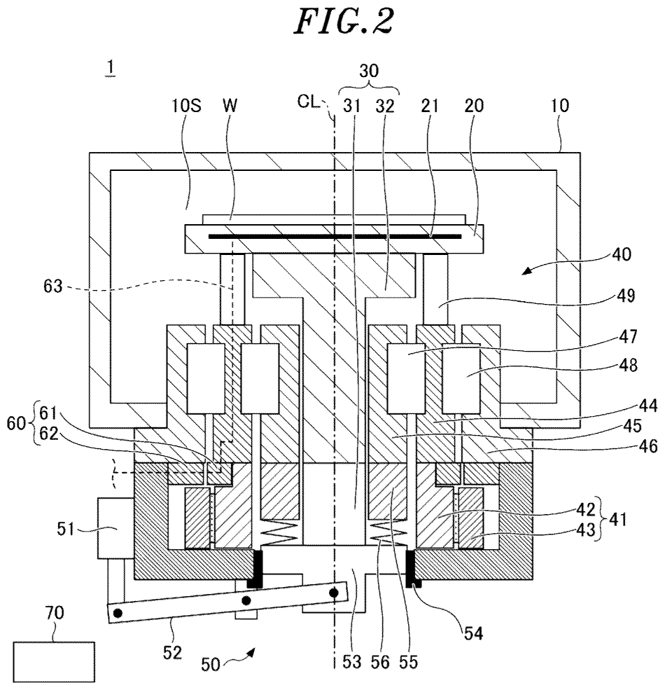

An example of the substrate processing apparatus 1 according to an embodiment will be described with reference to FIGS. 1 and 2. FIG. 1 is a cross-sectional view showing an example of a configuration of the substrate processing apparatus 1 according to an embodiment during rotation of a placing table 20. FIG. 2 is a cross-sectional view showing an example of the configuration of the substrate processing apparatus 1 according to the embodiment during cooling of the placing table 20.

The substrate processing apparatus 1 may be a substrate processing apparatus (e.g., a chemical vapor deposition (CVD) apparatus, an atomic layer deposition (ALD) apparatus, or the like) for performing desired processing on a substrate W by supplying a processing gas into a processing chamber 10, for example. Further, the substrate processing apparatus 1 may be a substrate processing apparatus (e.g., a physical vapor deposition (PVD) apparatus or the like) for performing desired processing (e.g., film formation or the like) on a substrate W by supplying a processing gas into the processing chamber 10 and sputtering a target disposed in the processing chamber 10, for example.

The substrate processing apparatus 1 includes the processing chamber 10, the placing table 20 on which a substrate W is placed in the processing chamber 10, a freezing device 30, a rotation device 40 for rotating the placing table 20, and a lifting/lowering device 50 for lifting and lowering the freezing device 30. The substrate processing apparatus 1 further includes a slip ring 60 for supplying a power to a chuck electrode 21 of the placing table 20 that is rotating. The substrate processing apparatus 1 further includes a controller 70 for controlling various devices such as the freezing device 30, the rotation device 40, and the lifting/lowering device 50.

The processing chamber 10 defines an inner space 10S. The processing chamber 10 is configured such that the inner space 10S is depressurized to an ultra-high vacuum by operating an exhaust device (not shown) such as a vacuum pump or the like. Further, a desired gas used for substrate processing is supplied into the processing chamber 10 through a gas supply line (not shown) communicating with a processing gas supply device (not shown).

The placing table 20 on which the substrate W is placed is disposed in the processing chamber 10. The placing table 20 is made of a material with high thermal conductivity (e.g., Cu). The placing table 20 includes an electrostatic chuck. The electrostatic chuck has a chuck electrode 21 embedded in a dielectric film. A predetermined potential is supplied to the chuck electrode 21 via a slip ring 60 and a wiring 63 that will be described later. With this configuration, the substrate W can be attracted to the electrostatic chuck and fixed to the upper surface of the placing table 20.

The freezing device 30 is disposed below the placing table 20. The freezing device 30 is formed by stacking a refrigerator 31 and a refrigeration medium 32. The refrigeration medium 32 can also be referred to as “cold link.” The refrigerator 31 holds the refrigeration medium 32, and cools the upper surface of the refrigeration medium 32 to an extremely low temperature. In view of cooling performance, the refrigerator 31 preferably uses a Gifford-McMahon (GM) cycle. The refrigeration medium 32 is fixed on the refrigerator 31, and the upper part thereof is accommodated in the processing chamber 10. The refrigeration medium 32 is made of a material having high thermal conductivity (for example, Cu), and has a substantially cylindrical outer shape. The refrigeration medium 32 is disposed such the center thereof coincides with a central axis CL of the placing table 20.

Further, the placing table 20 is rotatably supported by the rotation device 40. The rotation device 40 includes a rotation driving device 41, a fixed shaft 45, a rotation shaft 44, a housing 46, magnetic fluid seals 47 and 48, and a stand 49.

The rotational driving device 41 is a direct drive motor having a rotor 42 and a stator 43. The rotor 42 has a substantially cylindrical shape extending coaxially with the rotation shaft 44, and is fixed to the rotation shaft 44. The stator 43 has a substantially cylindrical shape with an inner diameter larger than the outer diameter of the rotor 42. The rotational driving device 41 may be in a form other than a direct drive motor, or may be in a form including a servomotor and a transmission belt.

The rotation shaft 44 has a substantially cylindrical shape extending coaxially with the central axis CL of the placing table 20. The fixed shaft 45 is provided inside the rotation shaft 44 in a radial direction. The fixed shaft 45 has a substantially cylindrical shape extending coaxially with the central axis CL of the placing table 20. The housing 46 is provided outside the rotation shaft 44 in the radial direction. The housing 46 has a substantially cylindrical shape extending coaxially with the central axis CL of the placing table 20 and is fixed to the processing chamber 10.

Further, the magnetic fluid seal 47 is provided between the outer peripheral surface of the fixed shaft 45 and the inner peripheral circumference of the rotation shaft 44. The magnetic fluid seal 47 rotatably supports the rotation shaft 44 with respect to the fixed shaft 45, and seals the gap between the outer peripheral surface of the fixed shaft 45 and the inner circumference of the rotation shaft 44 to separate the inner space 10S of the depressurizable processing chamber 10 from the outer space of the processing chamber 10. Further, the magnetic fluid seal 48 is provided between the inner peripheral surface of the housing 46 and the outer circumference of the rotation shaft 44. The magnetic fluid seal 48 rotatably supports the rotation shaft 44 with respect to the housing 46, and seals the gap between the inner peripheral surface of the housing 46 and the outer circumference of the rotation shaft 44 to separate the inner space 10S of the depressurizable processing chamber 10 from the outer space of the processing chamber 10. Accordingly, the rotation shaft 44 is rotatably supported by the fixed shaft 45 and the housing 46.

Further, the refrigeration medium 32 is inserted through the radially inner side of the fixed shaft 45.

The stand 49 is provided between the rotation shaft 44 and the placing table 20, and is configured to transmit the rotation of the rotation shaft 44 to the stand 49.

With the above configuration, when the rotor 42 of the rotation driving device 41 rotates, the rotation shaft 44, the stand 49, and the placing table 20 rotate relative to the refrigeration Medium 32 in the X1 Direction.

Further, the freezing device 30 is supported by the lifting/lowering device 50 to be vertically movable. The lifting/lowering device 50 includes an air cylinder 51, a link mechanism 52, a freezing device support 53, a linear guide 54, a fixed portion 55, and a bellows 56.

The air cylinder 51 is a mechanical device whose rod moves linearly by air pressure. The link mechanism 52 converts the linear motion of the rod of the air cylinder 51 into vertical motion of the freezing device support 53. Further, the link mechanism 52 has a lever structure, one end of which is connected to the air cylinder 51 and the other end of which is connected to the freezing device support 53. Accordingly, a large pressing force can be generated with a small thrust of the air cylinder 51. The freezing device support 53 supports the freezing device 30 (the refrigerator 31 and the refrigeration medium 32). Further, the moving direction of the freezing device support 53 is guided in the vertical direction by the linear guide 54.

The fixed portion 55 is fixed to the bottom surface of the fixed shaft 45. The substantially cylindrical bellows 56 surrounding the refrigerator 31 is provided between the bottom surface of the fixed portion 55 and the upper surface of the freezing device support 53. The bellows 56 is a metal bellows structure that is vertically extensible and contractible. Accordingly, the fixed portion 55, the bellows 56, and the freezing device support 53 seal the gap between the inner peripheral surface of the fixed shaft 45 and the outer circumference of the refrigeration medium 32 to separate the inner space 10S of the processing chamber 10 from the outer space of the processing chamber 10. Further, the bottom surface side of the freezing device support 53 is adjacent to the outer space of the processing chamber 10, and the region surrounded by the bellows 56 on the upper surface side of the freezing device support 53 is adjacent to the inner space 10S of the processing chamber 10.

The slip ring 60 is provided below the rotation shaft 44 and the housing 46. The slip ring 60 has a rotor 61 including a metal ring and a fixed body 62 including a brush. The rotor 61 has a substantially cylindrical shape extending coaxially with the rotation shaft 44, and is fixed to the bottom surface of the rotation shaft 44. The fixed body 62 has a substantially cylindrical shape with an inner diameter slightly larger than an outer diameter of the rotor 61, and is fixed to the bottom surface of the housing 46. The slip ring 60 is electrically connected to a DC power supply (not shown), and supplies a power from the DC power supply to the wiring 63 via the brush of the fixed body 62 and the metal ring of the rotor 61. With this configuration, a potential can be applied from the DC power supply to the chuck electrode 21 without twisting the wiring 63. The structure of the slip ring 60 may be a structure other than the brush structure, for example, a contactless power supply structure, a mercury-free structure, a structure containing a conductive liquid, or the like.

The controller 70 is, e.g., a computer, and includes a central processing unit (CPU), a random access memory (RAM), a read only memory (ROM), an auxiliary storage device, and the like. The CPU operates based on a program stored in the ROM or the auxiliary storage device to controls the operation of the substrate processing apparatus 1. The controller 70 may be installed inside the substrate processing apparatus 1, or may be installed outside the substrate processing apparatus 1. When the controller 70 is provided outside the substrate processing apparatus 1, the controller 70 can control the substrate processing apparatus 1 using a wired or wireless communication device.

In the case of performing desired processing on the substrate W, as shown in FIG. 1, the controller 70 controls the lifting/lowering device 50 (the air cylinder 51) to separate the placing table 20 and the refrigeration medium 32, and controls the rotation device 40 (the rotation driving device 41) to rotate the placing table 20 on which the substrate W is placed. Accordingly, the in-plane uniformity of substrate processing (e.g., film formation or the like) of the substrate W can be improved.

Further, in the case of cooling the placing table 20 and the substrate W placed on the placing table 20, as shown in FIG. 2, the controller 70 stops the rotation device 40 (the rotation driving device 41) to stop the rotation of the placing table 20, and controls the lifting/lowering device 50 (the air cylinder 51) to bring the placing table 20 and the refrigeration medium 32 into contact with each other. Accordingly, the substrate W placed on the placing table 20 can be cooled.

Here, if the pressing force for pressing the refrigeration medium 32 against the placing table 20 is insufficient, loss occurs in heat conduction, and the cooling performance for the placing table 20 is insufficient.

On the other hand, in the substrate processing apparatus 1, the upper surface (contact surface) of the refrigeration medium 32 is in direct contact with the bottom surface (surface to be contacted) of the placing table 20, and the refrigeration medium 32 is brought into contact with the placing table 20 and stops. Accordingly, the refrigeration medium 32 is in direct contact with the placing table 20, so that the cooling performance for the placing table 20 can be improved.

Further, by depressurizing the inner space 10S of the processing chamber 10 to a vacuum atmosphere, a pressure difference (vacuum pressure difference) is generated between the upper surface of the freezing device support 53 in a vacuum atmosphere and the bottom surface of the freezing device support 53 in an atmospheric atmosphere, which generates a pressing force for pressing the refrigeration medium 32 against the placing table 20. Therefore, the pressing force is applied to the refrigeration medium 32 by the thrust of the air cylinder 51 and the pressure difference (vacuum pressure difference) generated between the upper surface and the bottom surface of the freezing device support 53. Accordingly, when the refrigeration medium 32 is brought into contact with the placing table 20 to cool the placing table 20, even if the placing table 20 is thermally contracted, the refrigeration medium 32 may be raised to correspond to the thermal contraction of the placing table 20 by the pressing force.

Further, the vertical movement of the refrigeration medium 32 is guided by the freezing device support 53 and the linear guide 54. Accordingly, the refrigeration medium 32 can be raised and lowered in a state where the bottom surface (the surface to be contacted) of the placing table 20 and the upper surface (the contact surface) of the refrigeration medium 32 are maintained to be parallel to each other.

Further, a shim (not shown) is inserted into the refrigeration medium 32 to adjust parallelism of the upper surface (the contact surface) of the refrigeration medium 32 with respect to the bottom surface (the surface to be contacted) of the placing table 20.

Further, since the air cylinder 51 that is driven by air is used, the pressing force can be easily adjusted using an air pressure.

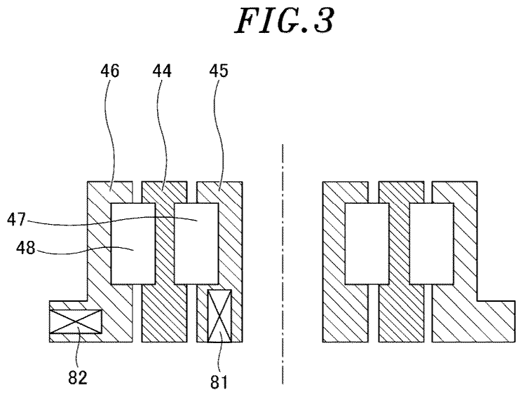

Here, the rotation device 40 will be further described with reference to FIG. 3. FIG. 3 is an example of a partially enlarged cross-sectional view of the rotation device 40 near the rotation shaft 44.

The magnetic fluid seal 47 is disposed on the outer diameter side of the fixed shaft 45 into which the refrigeration medium 32 (see FIGS. 1 and 2) is inserted to have a large seal diameter. Further, the magnetic fluid seal 48 is disposed on the outer diameter side of the rotation shaft 44 into which the refrigeration medium 32 (see FIGS. 1 and 2) and the fixed shaft 45 are inserted to have a large seal diameter. The magnetic fluid seals 47 and 48 with large seal diameters have large torque for rotating the rotation shaft 44. Therefore, a large high-torque motor is required as the rotation driving device 41 for rotating the rotation shaft 44, which increases the size of the device. In addition, a transformer for driving the high-torque motor is required, which increases the size of the device.

On the other hand, the magnetic fluid seals 47 and 48 are continuously rotated, so that the magnetic fluid self-heats and its viscosity decreases, and the torque for rotating the rotation shaft 44 is reduced. Therefore, the torque for rotating the rotation shaft 44 increases at the initial stage of the operation of the substrate processing apparatus 1.

Further, the increase in the temperature of the rotation device 40 due to the self-heating of the magnetic fluid may cause a temperature difference in the rotation device 40. Due to the difference in thermal expansion caused by the temperature difference, the rotation shaft 44 may be brought into contact with the fixed shaft 45 or the housing 46. Further, the temperature difference in the rotation device 40 tend to easily occur by abruptly increasing the rotational speed of the rotation shaft 44.

Therefore, during the warm-up operation of the rotation device 40 due to the self-heating of the magnetic fluid, the rotational speed of the rotation shaft 44 is increased in a stepwise manner while monitoring the temperature saturation, thereby suppressing the thermal expansion difference caused by the temperature difference.

On the other hand, in the substrate processing apparatus 1 according to an embodiment, the fixed shaft 45 is provided with a heater 81, and the housing 46 is provided with a heater 82. Further, the fixed shaft 45 is provided with a thermocouple (not shown) for detecting the temperature of the fixed shaft 45. Further, the housing 46 is provided with a thermocouple (not shown) for detecting the temperature of the housing 46. By providing the heaters 81 and 82 and the thermocouples at the fixed shaft 45 and the housing 46 that are non-rotating bodies, wiring can be easily formed. Further, by providing the heaters 81 and 82 at the fixed shaft 45 and the housing 46 that support the magnetic fluid seals 47 and 48, the magnetic fluid of the magnetic fluid seals 47 and 48 can be appropriately heated.

The controller 70 can operate the heaters 81 and 82 based on the temperature detected by the thermocouple to heat the fixed shaft 45 and the housing 46 to a desired temperature. Further, the magnetic fluid in the magnetic fluid seals 47 and 48 can be heated to a desired temperature.

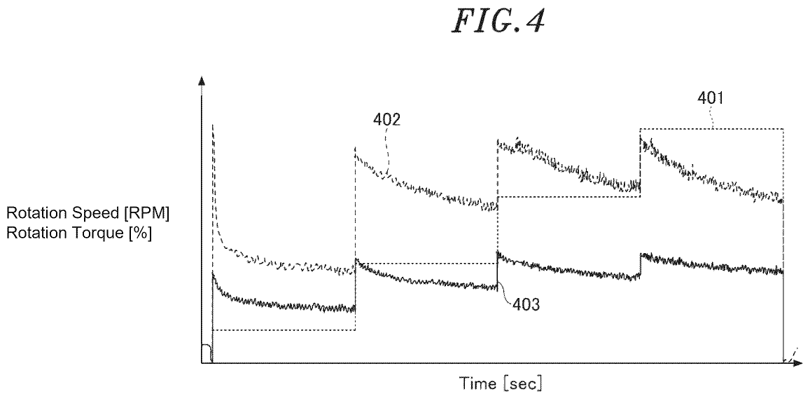

FIG. 4 is an example of a graph showing the rotational speed of the rotation shaft 44 and the torque for rotating the rotation shaft 44. The horizontal axis represents time. A dotted line 401 indicates the rotational speed of the rotation shaft 44. A dashed line 402 indicates the rotational torque of the rotation shaft 44 in a configuration in which the heaters 81 and 82 are not used. A solid line 403 indicates the rotational torque of the rotation shaft 44 in the case of adjusting the temperatures of the fixed shaft 45 and the housing 46 to 60° C. using the heaters 81 and 82.

Here, as shown by the dotted line 401, the rotational speed of the rotation shaft 44 is increased in a stepwise manner from 10 RPM to 70 RPM, for example. As indicated by the dotted line 402 and the solid line 403 for comparison, the rotational torque of the shaft 44 can be reduced by adjusting the temperatures of the fixed shaft 45 and the housing 46 to 60° C. using the heaters 81 and 82 compared to the configuration in which the heaters 81 and 82 are not used.

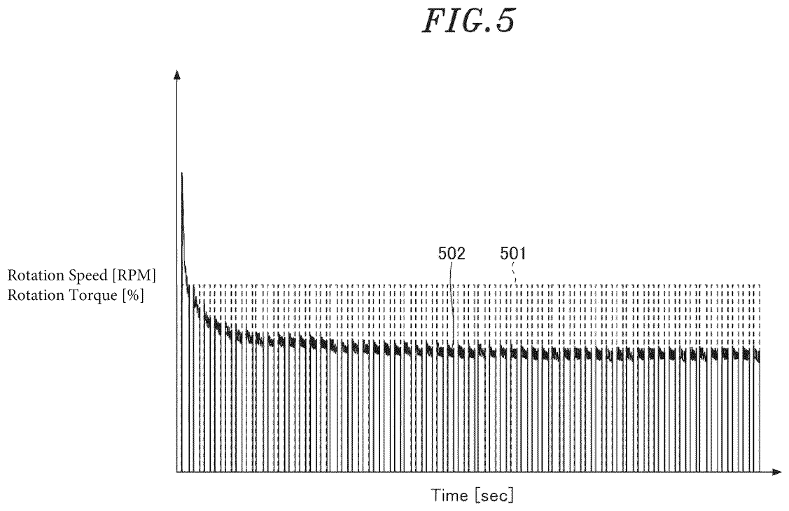

FIG. 5 is an example of a graph showing the relationship between the rotational speed and rotational torque of the rotation shaft 44. The horizontal axis represents time. A dashed line 501 indicates the rotational speed of the rotation shaft 44. A solid line 502 indicates the rotational torque of the rotation shaft 44 in the case of adjusting the temperatures of the fixed shaft 45 and the housing 46 to 60° C. using the heaters 81 and 82.

The maximum value of the rotational torque in the case of starting rotation of the rotation shaft 44 at a high rotational speed (e.g., 70 RPM) in the configuration using the heaters 81 and 82 which is indicated by the solid line 502 in FIG. 5 is smaller than the maximum value of the rotational torque in the case of starting rotation of the rotation shaft 44 at a low speed (e.g., 10 RPM) in the configuration using no heaters 81 and 82 which is indicated by the dashed line 402 in FIG. 4. Accordingly, the rotation shaft 44 can be rotated at a high rotational speed (e.g., 70 RPM) without performing the warm-up operation in which the rotational speed of the rotation shaft 44 is gradually increased while monitoring temperature saturation. Hence, the time required for the warm-up operation of the substrate processing apparatus 1 can be reduced, and the productivity of the substrate processing apparatus 1 can be improved. Further, by reducing the time required for the warm-up operation of the substrate processing apparatus 1, contribution to the energy saving effect can be expected. Further, by performing heating using the heaters 81 and 82 even when the substrate processing apparatus 1 is not in operation, the recovery time after an idle state or after maintenance can be shortened.

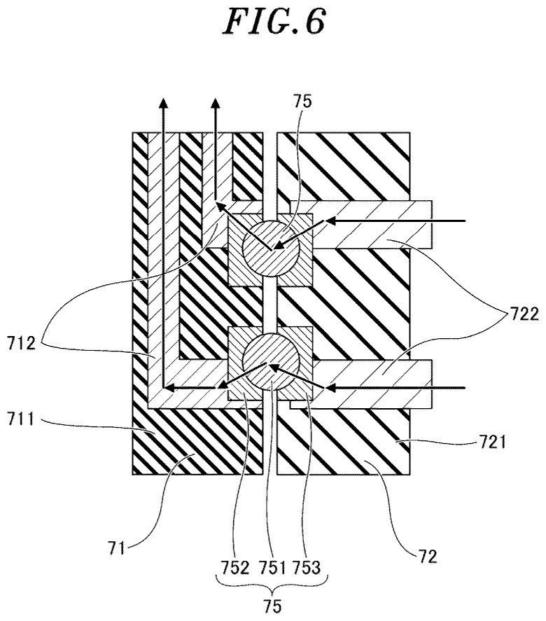

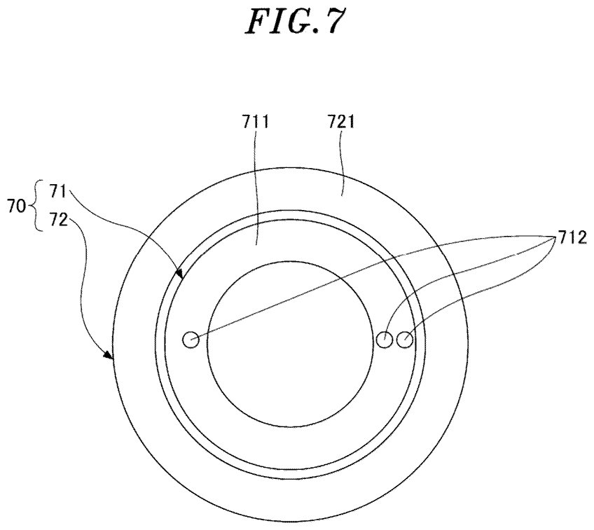

Next, the configuration of the slip ring 60 will be described with reference to FIGS. 6 and 7. FIG. 6 is an example of a cross-sectional view of the slip ring 60. FIG. 7 is an example of a plan view of the slip ring 60 viewed from above.

The slip ring 60 includes a rotor 71 that is fixed to the bottom surface of the rotation shaft 44 and rotates together with the rotation shaft 44, and a stator 72 that is fixed to the bottom surface of the housing 46. A bearing part 75 is disposed between the rotor 71 and the stator 72. The bearing part 75 includes a rolling body 751, an inner ring 752, and an outer ring 753. The rolling body 751, the inner ring 752, and the outer ring 753 are conductive members, and the inner ring 752 and the outer ring 753 are electrically connected via the rolling body 751. Further, the rolling body 751 may be coated with conductive grease. The rotor 71 has an insulating portion 711 made of resin or the like, and conductive portions 712. The conductive portions 712 are electrically connected to the inner ring 752. The stator 72 includes an insulating portion 721 made of resin or the like, and conductive portions 722. The conductive portions 722 are electrically connected to the outer ring 753.

With such a configuration, the conductive portions 722 of the stator 72 and the conductive portions 712 of the rotor 71 are electrically connected via the bearing part 75. Accordingly, the height of the slip ring in the axial direction can be reduced compared to the slip ring including the stator having the brush and the rotor 61 having the metal ring. Further, the slip ring 60 with a large diameter can be formed.

Further, as shown in FIG. 7, the conductive portions 712 may be disposed at the same phase or different phases when viewed in the circumferential direction of the slip ring 60. Further, although the case where the conductive portions 712 are disposed on the upper surface of the rotor 71 has been described, the present disclosure is not limited thereto, and the conductive portions 712 may be disposed on the bottom surface of the rotor 71, or the inner peripheral surface of the rotor 71. Further, although the case where the conductive portions 722 are disposed on the outer peripheral surface of the stator 72 has been described, the present disclosure is not limited thereto, and the conductive portions 722 may be disposed on the bottom surface of the stator 72, or the upper surface of the stator 72.

While the substrate processing apparatus 1 has been described above, the present disclosure is not limited to the above embodiments, and various changes and improvements can be made without departing from the scope of the appended claims and the gist thereof.

This application claims priority to Japanese Patent Application No. 2022-14449 filed on Feb. 1, 2022, the entire contents of which are incorporated herein by reference.

### DESCRIPTION OF REFERENCE NUMERALS

W: substrate

CL: central axis

1: substrate processing apparatus

10: processing chamber

10S: inner space

20: placing table

21: chuck electrode

30: freezing device

31: refrigerator

32: refrigeration medium

40: rotation device

41: rotation driving device

42: rotor

43: stator

44 rotation shaft

45: fixed shaft

46: housing

47, 48: magnetic fluid seal

47: magnetic fluid seal

48: magnetic fluid seal

49: stand

50: lifting/lowering device

51: air cylinder

52: link mechanism

53: freezing device support

54: linear guide

55: fixed part

56: bellows

60: slip ring

61: rotor

62: stator

63: wiring

70: controller

71: rotor

72: stator

75: bearing part

81, 82: heater

751: rolling body

752: inner ring

753: outer ring

711, 721: insulating portion

712, 722: conductive portion

1. A substrate processing apparatus comprising:
a placing table disposed in the processing chamber and on which a substrate is placed;
a rotation shaft configured to support the placing table;
a housing configured to rotatably support the rotation shaft;
a magnetic fluid seal disposed between the rotation shaft and the housing; and
a heater configured to adjust a temperature of the magnetic fluid seal.

2. The substrate processing apparatus of claim 1, wherein the heater is disposed at the housing.

3. The substrate processing apparatus of claim 2, further comprising:
a thermocouple disposed at the housing.

4. The substrate processing apparatus of claim 1, further comprising:
a rotor fixed to the rotation shaft and having a conductive portion;
a stator fixed to the housing and having a conductive portion; and
a conductive bearing part disposed between the rotor and the stator,
wherein the conductive portion of the rotor and the conductive portion of the stator are electrically connected via the bearing part.

5. The substrate processing apparatus of claim 2, further comprising:
a rotor fixed to the rotation shaft and having a conductive portion;
a stator fixed to the housing and having a conductive portion; and
a conductive bearing part disposed between the rotor and the stator,
wherein the conductive portion of the rotor and the conductive portion of the stator are electrically connected via the bearing part.

6. The substrate processing apparatus of claim 3, further comprising:
a rotor fixed to the rotation shaft and having a conductive portion;
a stator fixed to the housing and having a conductive portion; and
a conductive bearing part disposed between the rotor and the stator,
wherein the conductive portion of the rotor and the conductive portion of the stator are electrically connected via the bearing part.
